(19) United States
(12) Patent Application Publication
(10) Pub. No.: US 2012/0090676 A1
(43) Pub. Date: Apr. 19, 2012

(54) THIN-FILM SOLAR CELL AND METHOD FOR MANUFACTURING THE SAME

(75) Inventors: Chih-Hsiung Lin, Tainan (TW); Yu-Tsang Chien, Tainan (TW); Chih-Hsiung Chang, Tainan (TW); Kun-Chih Lin, Tainan (TW); Yueh-Hsun Lee, Tainan (TW)

(73) Assignee: AURIA SOLAR CO., LTD., Tainan (TW)

(21) Appl. No.: 13/331,100

(22) Filed: Dec. 20, 2011

(30) Foreign Application Priority Data
Dec. 29, 2010 (TW) 099146608
Jul. 27, 2011 (TW) 100126679

(51) Int. Cl. H01L 31/0352; H01L 31/18

(52) U.S. Cl. 136/255; 438/87; 257/E31.032

(57) ABSTRACT

A thin-film solar cell and a method for manufacturing the same are presented, in which the dopant concentration turns low in a sloping way. The solar cell includes a substrate, a first contact region, a photoelectric conversion layer, and a second contact region. The first contact region a photoelectric conversion layer, and a second contact region are disposed on the substrate. At least one of the first contact region and the second contact region contains an N-type dopant, and the concentration of the N-type dopant is decreased gradually in a direction towards the photoelectric conversion layer. Through the thin-film solar cell and the method for manufacturing the same, the conversion efficiency of the solar cell is improved, and the thin-film solar cell and the manufacturing method are capable of being integrated with an existing manufacturing process of a solar cell, thereby simplifying the manufacturing process and reducing the cost.

### CROSS-REFERENCE TO RELATED APPLICATIONS

This non-provisional application claims priority under 35 U.S.C. §119(a) on Patent Application No(s). 099146608 filed in Taiwan, R.O.C. on Dec. 29, 2010 and Patent Application No. 100126679 filed in Taiwan, R.O.C. on Jul. 27, 2011, the entire contents of which are hereby incorporated by reference.

### BACKGROUND

1. Technical Field

The present disclosure relates to a thin-film solar cell and a method for manufacturing the same, and more particularly to a thin-film solar cell having a contact in which the dopant concentration turns low in a sloping way, and a method for manufacturing the same.

2. Related Art

Currently, most of the solar cell technologies employ solar cell materials to convert sunlight into electricity. Among them, silicon-based solar cells are common in the industry. In the silicon-based solar cells, high-purity semiconductor materials (for example, silicon) are doped with various dopants to present different properties. For example, P-type semiconductor is formed by doping Group-IV atoms with Group-III atoms, and, on the other hand, N-type semiconductor is formed by doping the Group-IV atoms with Group-V atoms. Then, a P-N junction is formed through the combination of P-type and the N-type semiconductors. When sunlight is incident on a semiconductor having the P-N junction, electrons in the semiconductor can be excited due to the energy of photons, so that electron-hole pairs are generated. After that, the electron and the hole move in two opposite directions in an electric field respectively due to their potential. If the solar cell is connected to a load through wires, a circuit loop will be formed, and current will be supplied to the load from the solar cell.

A conventional tandem solar cell includes, from a light receiving surface in sequence, a substrate, a front contact, a photoelectric conversion layer and a back contact. In the natural world, most transparent contact materials are N-type semiconductors, such as zinc oxide, tin oxide or indium oxide. Accordingly, when sun light is incident on the solar cell, a schottcky barrier is formed at the junction of the P-type photoelectric conversion layer and the N-type contact. However, such schottcky barrier impedes the holes' move toward contact layer, and, therefore, the recombination rate of the electrons and the holes rises. As a result, the series resistance of the solar cell increases, and thus the photoelectric conversion efficiency of the solar cell is adversely influenced.

In another aspect, if the N-type contact is joined to the N-type photoelectric conversion layer, the Group-III dopants in the contact layer will diffuse into the N-type semiconductor layer, which is doped with Group-V atoms, through heating process. Such diffusion of the Group-III atoms weakens the electric field built by the Group-V atoms in the N-type photoelectric conversion layer, and the lower carrier concentration also deteriorates the open circuit potential (V_{oc}), the filled factor, and the photoelectric conversion efficiency of the solar cell.

### SUMMARY

Accordingly, the present disclosure is a thin-film solar cell and a method for manufacturing the same, in which the dopant concentration of a contact region turns low in a sloping way, so as to solve the problems in the prior art and to maintain a certain photoelectric conversion efficiency of the solar cell.

The present disclosure provides a thin-film solar cell, which comprises a substrate, a first contact region, a photoelectric conversion layer, and a second contact region.

The first contact region is disposed on the substrate, the photoelectric conversion layer is disposed on the first contact region, and the second contact region is disposed on the photoelectric conversion layer. At least one of the first contact region and the second contact region contains N-type dopants, and the concentration of the N-type dopants turns low in a sloping way towards the photoelectric conversion layer.

According to an embodiment of the present disclosure, the first contact region and the second contact region both contain the N-type dopants, the first contact region comprises a first contact layer and at least one first buffer contact layer, and the second contact region comprises a second contact layer and at least one second buffer contact layer. The first contact layer is disposed on the substrate, and the first buffer contact layer is disposed on the first contact layer. The concentration of the N-type dopants in the first contact layer is higher than that in the first buffer contact layer. The second buffer contact layer is disposed on the photoelectric conversion layer, and the second contact layer is disposed on the second buffer contact layer. The concentration of the N-type dopants in the second contact layer is higher than that in the second buffer contact layer.

According to an embodiment of the present disclosure, the photoelectric conversion layer comprises a P-type semiconductor layer adjacent to the first contact region and an N-type semiconductor layer adjacent to the second contact region.

According to an embodiment of the present disclosure, the N-type dopants for the contact layer are selected from the group consisting of boron (B), aluminum (Al), gallium (Ga), and indium (In).

The present disclosure also provides a method for manufacturing a thin-film solar cell, which comprises the following steps. A first contact region on a substrate is formed. A photoelectric conversion layer is formed on the first contact region. And, a second contact region is formed on the photoelectric conversion layer. At least one of the first contact region and the second contact region contains N-type dopants, and the concentration of the N-type dopants turns low in a sloping way towards the photoelectric conversion layer.

According to an embodiment of the present disclosure, the step of forming the first contact region comprises: forming (R+1) contact material layers on the substrate sequentially, and the concentration of the N-type dopant of the R^{th} contact layer is higher than that of the (R+1)^{th} contact layer, and R is a positive integer.

According to an embodiment of the present disclosure, the step of forming the first contact region comprises: forming a transparent conductive oxide (TCO) layer on the substrate; and doping the TCO layer with the N-type dopants.

According to an embodiment of the present disclosure, the step of forming the second contact region comprises: forming (S+1) contact material layers on the photoelectric conversion layer sequentially, and the concentration of the N-type dopants in a S^{th} contact layer is lower than that of the (S+1)^{th} contact layer, and S is a positive integer.

According to an embodiment of the present disclosure, the step of forming the second contact region comprises: forming a TCO layer on the photoelectric conversion layer; and doping the TCO layer with the N-type dopant.

In the thin-film solar cell and the method for manufacturing the same according to the present disclosure, at least one of the first contact region and the second contact region has the N-type dopants of which the concentration turns low in the sloping way towards the photoelectric conversion layer, thereby improving the efficiency of the solar cell. Moreover, the thin-film solar cell and the method for manufacturing the same according to the present disclosure can be integrated with an existing manufacturing process of a solar cell, thereby the manufacturing process for the solar cell is improved and the cost of the solar cell is reduced.

### BRIEF DESCRIPTION OF THE DRAWINGS

The present disclosure will become more fully understood from the detailed description given herein below for illustration only, and thus are not limitative of the present disclosure, and wherein:

FIG. 1 is a flow chart of a method for manufacturing a thin-film solar cell according to the present disclosure;

FIG. 2 is a cross-sectional structural view of a thin-film solar cell according to the present disclosure;

FIG. 3A is a cross-sectional structural view of a thin-film solar cell according to a first embodiment of the present disclosure;

FIG. 3B is a cross-sectional structural view of the thin-film solar cell according to the first embodiment of the present disclosure;

FIG. 4A is a cross-sectional structural view of a thin-film solar cell according to a second embodiment of the present disclosure;

FIG. 4B is a cross-sectional structural view of the thin-film solar cell according to the second embodiment of the present disclosure;

FIG. 5A is a cross-sectional structural view of the thin-film solar cell according to FIGS. 3A and 3B; and

FIG. 5B is a cross-sectional structural view of the thin-film solar cell according to FIGS. 4A and 4B.

### DETAILED DESCRIPTION

The detailed features and advantages of the present disclosure are described below in great detail through the following embodiments, the content of the detailed description is sufficient for persons skilled in the art to understand the technical content of the present disclosure and to implement the present disclosure there accordingly. Based upon the content of the specification, the claims, and the drawings, persons skilled in the art can easily understand the relevant objectives and advantages of the present disclosure.

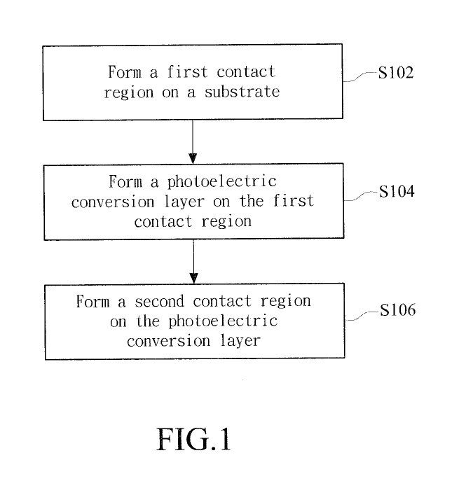

FIG. 1 is a flow chart of a method for manufacturing a thin-film solar cell according to an embodiment of the present disclosure. The manufacturing method is suitable for forming a front contact or a back contact in which the dopant concentration turns low in a sloping way, so as to maintain good photoelectric conversion efficiency of the solar cell. The method for manufacturing the thin-film solar cell according to the present disclosure mainly comprises the following steps.

In Step S102, a first contact region is formed on a substrate.

In Step S104, a photoelectric conversion layer is formed on the first contact region.

In Step S106, a second contact region is formed on the photoelectric conversion layer.

At least one of the first contact region and the second contact region contains N-type dopants, and the concentration of the N-type dopant turn low in the sloping way towards the photoelectric conversion layer.

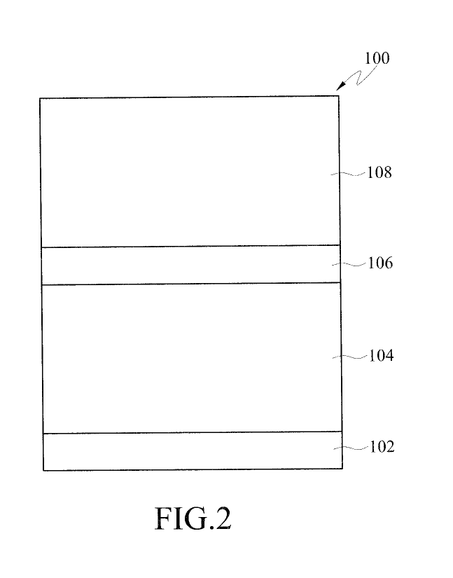

FIG. 2 is a cross-sectional structural view of a thin-film solar cell according to an embodiment of the present disclosure. It can be seen in FIG. 2 that, the thin-film solar cell 100 comprises a substrate 102 and a first contact region 104, a photoelectric conversion layer 106 and a second contact region 108 disposed on the substrate 102. The first contact region 104 is disposed on the substrate 102, the photoelectric conversion layer 106 is disposed on the first contact region 104, and the second contact region 108 is disposed on the photoelectric conversion layer 106. In this embodiment, at least one of the first contact region 104 and the second contact region 106 contains N-type dopants and the concentration of the N-type dopants decreases in the direction towards the photoelectric conversion layer 106. In the following embodiments, at least one of the first contact region 104 and the second contact region 108 is made of zinc oxide (ZnO) doped with N-type dopants selected from the Group-III elements, such as boron (B), aluminum (Al), gallium (Ga) and indium (In), wherein the valence of the zinc atom is two. In some embodiments, contacts different in material from those in following embodiments may be formed by adjusting the energy level generated by donors and the acceptors.

In some embodiments, the first contact region 104 contains N-type dopants, and the concentration of the N-type dopant on the surface of the first contact region 104 in contact with the photoelectric conversion layer 106 is lowest in the first contact region 104; in some embodiments, the second contact region 108 contains N-type dopants, and the concentration of the N-type dopant on the surface of the second contact region 108 in contact with the photoelectric conversion layer 106 is lowest in the second contact region 108. In further some embodiments, both the first contact region 104 and the second contact region 108 contain N-type dopants, and the concentrations of the N-type dopant in the first contact region 104 and the second contact region 108 decreases in the directions towards the photoelectric conversion layer 108.

In other words, according to the method for manufacturing the thin-film solar cell of the present disclosure, the N-type dopant concentrations in the first contact region 104 and the second contact region 108 are controlled to be lower in the portion of each contact regions 104 and 108 close to the photoelectric conversion layer 106 than that in other portion of the same contact regions. For a method for forming such a concentration gradient, reference is made to the following first embodiment (a multi-layer structure) and the second embodiment (a gradient structure) of the present disclosure, and the details will be described below.

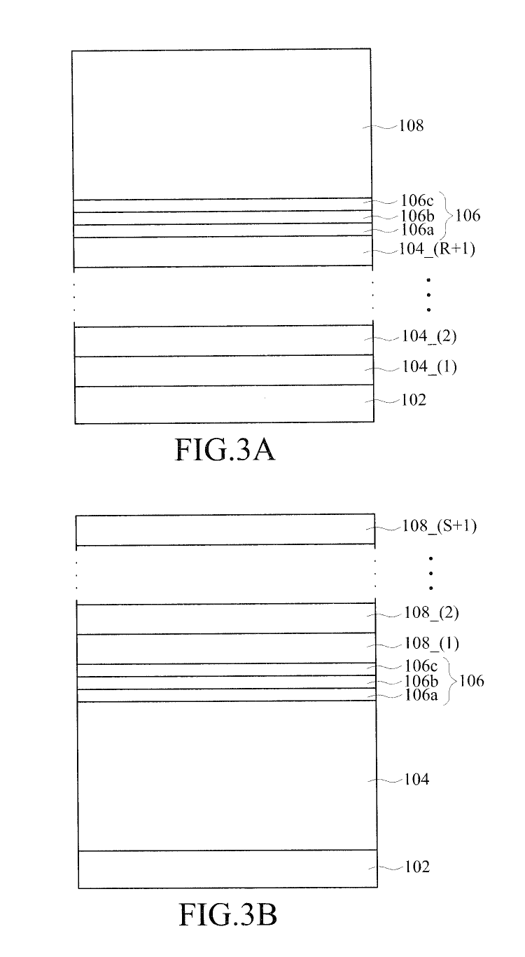

As shown in FIG. 3A, according to the first embodiment of the present disclosure, generally, the substrate 102 may be a transparent substrate, and the material of the substrate 102 may be, but not limited to, glass or transparent resin. Taking this embodiment as an example, based on the use for photoelectric conversion of the photoelectric conversion layer 106, the term, “transparent substrate” means substrates through which light capable of being converted by the photoelectric conversion layer 106 can pass. Accordingly, such light is not limited to visible light. Furthermore, the term, “transparent substrate,” does not mean that 100% of the light can penetrate the substrate 102. Substrates which most of the light can penetrate fall within the scope of the present disclosure.

A method for forming the first contact region 104 capable of serving as a front contact on the substrate 102 comprises, for example, forming (R+1) contact material layers on the substrate 102 sequentially, in which R is any positive integer. The material of the contact material layer is, for example, a transparent conductive oxide (TCO) doped with N-type dopants. The material of the TCO, such as zinc oxide (ZnO), indium oxide (In₂O₃), Al doped ZnO (AZO), or indium tin oxide (ITO), is doped with a Group-III element (for example, boron) to form a transparent N-type semiconductor, wherein the valence of the zinc atom is two. It should be noted that, when the (R+1) contact material layers are sequentially deposited, the N-type dopant concentration of the R^{th} contact material layer is higher than that of the (R+1)^{th} contact material layer. That is to say, the N-type dopant concentration in the first contact region 104 turns low in a sloping way towards the photoelectric conversion layer 106.

Specifically, the method for forming the first contact region 104 comprises forming a 1^{st} contact material layer 104_(1) on an upper surface of the substrate 102, then forming a 2^{nd} contact material layer 104_(2) on the 1^{st} contact material layer 104_(1), and then forming a 3^{rd} contact material layer, a 4^{th} contact material layer, . . . , and the (R+1)^{th} contact material layer 104_(R+1) sequentially, in which the N-type dopant concentration in the 1^{st} contact material layer 104_(1) closest to the substrate 102 is higher than that of the 2^{nd} contact material layer 104_(2). Thus, it can be understood that, the (R+1)^{th} contact material layer 104_(R+1) is a part of the first contact region 104 having the lowest N-type dopant concentration, and the N-type dopant concentrations decrease from the 1^{st} contact material layer 104_(1) to the (R+1)^{th} contact material layer 104_(R+1). In this way, the 2^{nd} contact material layer, the 3^{rd} contact material layer, the 4^{th}contact material layer, . . . , and the (R+1)^{th} contact material layer 104_(R+1) function as buffer contact layers of the 1^{st} contact material layer 104_(1) in the first contact region 104, in which the N-type dopant concentration is decreased layer by layer.

Through stacking buffer contact layers having different N-type dopant concentration, the N-type dopant concentration of the contact region decreases in a direction towards the photoelectric conversion layer 106. In some embodiments, the N-type dopant concentration is in a range from 0 cm⁻³ to 10²⁰ cm⁻³. When the N-type dopant concentration is 0 cm⁻³, the thickness of the buffer contact layer is, for example, 50 nanometer; when the N-type dopant concentration is 10²⁰ cm⁻³, the thickness of the buffer contact layer is, for example, 200 nanometer.

It should be noted that, in the embodiment in FIG. 3A, the first contact region 104 having more than two contact material layers are taken as an example, and the present disclosure is not limited thereto. People of ordinary skill in the art can adjust the number of the buffer contact layers and the thickness and the material of each buffer contact layer in the first contact region 104 according to specification and the conditions in the manufacturing process, as long as the N-type dopant concentration in the (R+1) contact material layers is decreased gradually in the direction towards the photoelectric conversion layer 106.

After the first contact region 104 is formed on the substrate 102, the photoelectric conversion layer 106 and the second contact region 108 are formed on the first contact region 104 sequentially to complete the thin-film solar cell 100.

In this embodiment, the photoelectric conversion layer 106 comprises, for example, a P-type semiconductor layer 106a, an intrinsic layer 106b and an N-type semiconductor layer 106c and is formed through radio frequency plasma enhanced chemical vapor deposition (RF PECVD), very high frequency plasma enhanced chemical vapor deposition (VHF PECVD) or microwave plasma enhanced chemical vapor deposition (MW PECVD). The P-type semiconductor layer 106a, the intrinsic layer 106b and the N-type semiconductor layer 106c are formed on the first contact region 104 sequentially. The material of the P-type semiconductor layer 106a is, for example, amorphous silicon or microcrystal silicon, and the material doped in the P-type semiconductor layer 106a is, for example, selected from the Group-IIIA elements in the Periodic Table of Elements, such as boron (B), aluminum (Al), gallium (Ga), indium (In), or thallium (Tl). The material of the intrinsic layer 106b is, for example, undoped amorphous silicon or microcrystal silicon and serves as a main region for light to generate electron-hole pairs. The material of the N-type semiconductor layer 106c is, for example, amorphous silicon or microcrystal silicon, and the material doped in the N-type semiconductor layer 106c is, for example, selected from the Group-VA elements in the Periodic Table of Elements such as phosphorus (P), arsenic (As), stibium (Sb), or bismuth (Bi). In some embodiment, the photoelectric conversion layer 106 may also comprise an N-type semiconductor layer, an intrinsic layer and a P-type semiconductor layer which are formed on the first contact region 104 sequentially. Furthermore, in other embodiments, the photoelectric conversion layer 106 may also be formed by stacking a plurality of tandem structures, in which each tandem structure comprises an N-type semiconductor layer, an intrinsic layer and a P-type semiconductor layer. The number or structure of the photoelectric conversion material layers used in the photoelectric conversion layer 106 is not limited in the present disclosure and can be changed by persons of ordinary skill in the art according to requirements.

Then, the second contact region 108 is formed on the photoelectric conversion layer 106 and serves as a back contact of the thin-film solar cell 100, so as to complete the thin-film solar cell 100. The material of the second contact region 108 comprises a TCO, for example, Zinc oxide (ZnO), AZO, In₂O₃, or other transparent conductive materials.

Therefore, in the thin-film solar cell 100, the first contact region 104 is made of the transparent conductive material containing the N-type dopant for forming the N-type semiconductor. In order to avoid the schottcky barrier at the interface between the N-type contact 104 and the P-type semiconductor layer 106, in the first contact region 104 of the first embodiment, the N-type dopant concentration of at least one buffer contact is lower than that of the first contact material layer 104_(1). Accordingly, the N-type dopant concentration on an interface between the first contact region 104 and the photoelectric conversion layer 106, is reduced, so that the carrier recombination at the interface between the first contact region 104 and the photoelectric conversion layer 106 is reduced, and the photoelectric conversion efficiency of the photoelectric conversion layer 106 is improved.

In addition, as the N-type dopant concentration of a front contact region turns lower in a sloping way towards the photoelectric conversion layer, according to the present disclosure, low TCO resistance and low schottcky barrier can be both achieved in the thin-film solar cell, thereby the efficiency of the solar cell is further improved.

Besides, by the same taken, a back contact region of the thin-film solar cell 100 may also comprise buffer contact layers with different N-type dopant concentration to form a decreasing N-type dopant concentration gradient in the second contact region 108. As shown in FIG. 3B, the substrate 102, the first contact region 104 and the photoelectric conversion layer 106 comprised in the thin-film solar cell 100 are the same as those described above and will not be described herein again. However, with respect to the second contact region 108 in FIG. 3B, the step of forming the second contact region 108 comprises, for example, forming (S+1) contact material layers on the photoelectric conversion layer 106 sequentially, and S is a positive integer.

The material of the contact material layers is, for example, a TCO doped with N-type dopants. In this embodiment, the material of the TCO is, for example, ZnO, In₂O₃, AZO, or ITO, and is doped with atoms selected from higher-valence elements to form a transparent conductive N-type semiconductor. For example, the Group-III element boron, which donors three valence electrons, is doped into ZnO to substitute the Zn atom, which contributes two valence electrons. It should be noted that, when the (S+1) contact material layers are sequentially deposited, the N-type dopant concentration of the S^{th} contact material layer is lower that that of the (S+1)^{th} contact material layer. That is to say, in the second contact region 108, the N-type dopant concentration is decreased gradually in the direction towards the photoelectric conversion layer 106, so that the N-type dopant concentration of a 1^{st} contact material layer 108_(1) closest to the photoelectric conversion layer 106 is the lowest in the second contact region 108. In this way, the 1^{st} contact material layer, a 2^{nd} contact material layer, a 3^{rd} contact material layer, . . . , and the S^{th} contact material layer 108_(S) can serve as buffer contact layers of the (S+1)^{th} contact material layer 108_(S+1) in the second contact region 108, and the N-type dopant concentration is increased layer by layer. In some embodiments, a series of chambers for doping arranged from hot to cool sequentially are used to form the contact region. That is to say, the (R+1) contact material layers are formed on the substrate 102 by transferring the substrate 102 from the hot chamber to the cool chamber. As a result, the contact material layer formed in the hotter chamber contains more N-type dopant than that formed in the cooler chamber. By controlling the environment temperature at which the contact material is formed, the N-type dopant concentration can be controlled to decrease towards the photoelectric conversion layer. In some embodiments, the N-type dopant concentration is in a range between 0 cm⁻³ to 10²⁰ cm⁻³. When the N-type dopant concentration is 0 cm⁻³, the thickness of the buffer contact layer is, for example, 50 nanometer; when the N-type dopant concentration is 10²⁰ cm⁻³, the thickness of the buffer contact layer is, for example, 200 nanometer.

In the thin-film solar cell 100, the second contact region 108 is made of the transparent conductive material containing the N-type dopant. The problems of low open circuit potential, filled factor and photoelectric conversion efficiency due to the diffusion of the N-type dopant from the second contact region 108 are prevented by forming a buffer contact layer having lower N-type dopant concentration than (S+1)^{th} contact material layer 108_(S+1) and, therefore, the N-type dopant concentration in the interface between the second contact region 108 and the N-type semiconductor layer 106c is reduced. In this embodiment, the valence of the dopants of the second contact region 108 (for example, the valence of boron is three) is different from that of the dopant of the N-type semiconductor layer 106c (for example, the valence of phosphorus is five), so that the problem of low photoelectric conversion efficiency due to the diffusion of the N-type dopant from the second contact region 108 is reduced by gradually decreasing the N-type dopant concentration in the direction towards the photoelectric conversion layer.

Similarly, the first contact region 104 having more than two contact material layers are taken as an example, and the present disclosure is not limited thereto. People of ordinary skill in the art can adjust the total number of buffer contact layers and the thickness and the material of each buffer contact layer in the second contact region 108 according to specification and the conditions in the manufacturing process, as long as the N-type dopant concentration in the (S+1) contact material layers is decreased gradually in the direction towards the photoelectric conversion layer 106.

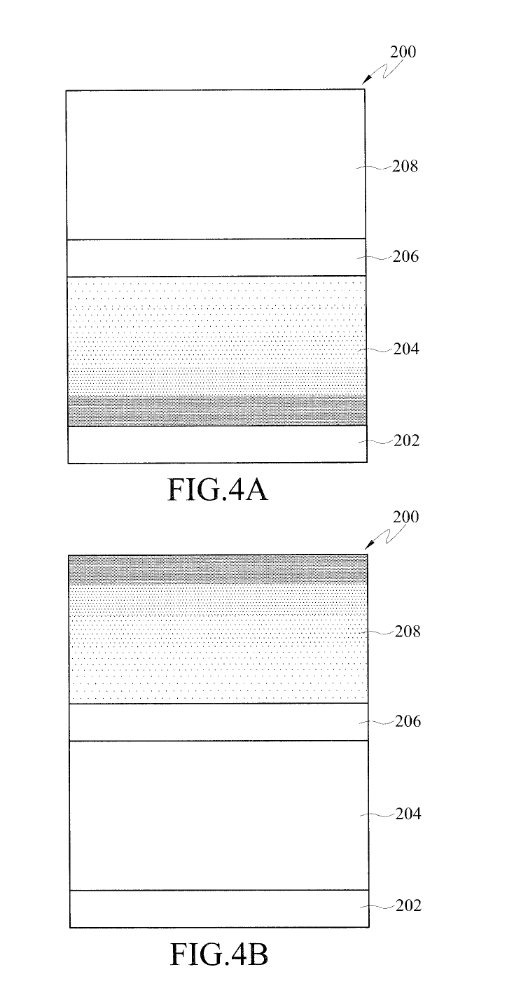

The method for forming the decreasing concentration gradient is not limited to the multi-layer structure according to the first embodiment of the present disclosure. In a second embodiment of the present disclosure, as shown in FIGS. 4A and 4B, a front contact or a back contact having of which the dopant concentration turns lower in a sloping way is a single-layer structure.

A thin-film solar cell 200 comprises a substrate 202 and a first contact region 204, a photoelectric conversion layer 206 and a second contact region 208 which are disposed on the substrate 202. The thin-film solar cell 200 is similar to the thin-film solar cell 100 of the first embodiment, and the differences between the second embodiment and the first embodiment mainly lie in the method for forming the first contact region 204 and the second contact region 208 and the structure thereof.

As shown in FIG. 4A, the method for forming the first contact region 204 comprises, for example, forming a TCO layer on a surface of the substrate 202 through chemical vapor deposition (CVD), physical vapor deposition (PVD) or spraying; then, doping the TCO layer with N-type dopants. According to the second embodiment of the present disclosure, the concentration distribution of the N-type dopant in the TCO layer can be adjusted by controlling parameters such as implantation energy, concentration or diffusion when the N-type dopant is implanted, so that the distribution of the N-type dopant in the TCO layer is substantially changed with the thickness, that is, the dopant concentration is decreased gradually in a direction towards the photoelectric conversion layer 206.

Similarly, as shown in FIG. 4B, the method for forming the second contact region 208 comprises, for example, forming a TCO layer on the photoelectric conversion layer 206 through CVD, PVD or spraying; and then, doping the TCO layer with N-type dopants. According to the second embodiment of the present disclosure, the concentration distribution of the N-type dopant in the TCO layer can be adjusted by controlling the parameters such as implantation energy, concentration or diffusion when the N-type dopant is implanted, so that the distribution of the N-type dopant in the TCO layer is substantially changed with the thickness, that is, the dopant concentration is decreased gradually in a direction towards the photoelectric conversion layer 206.

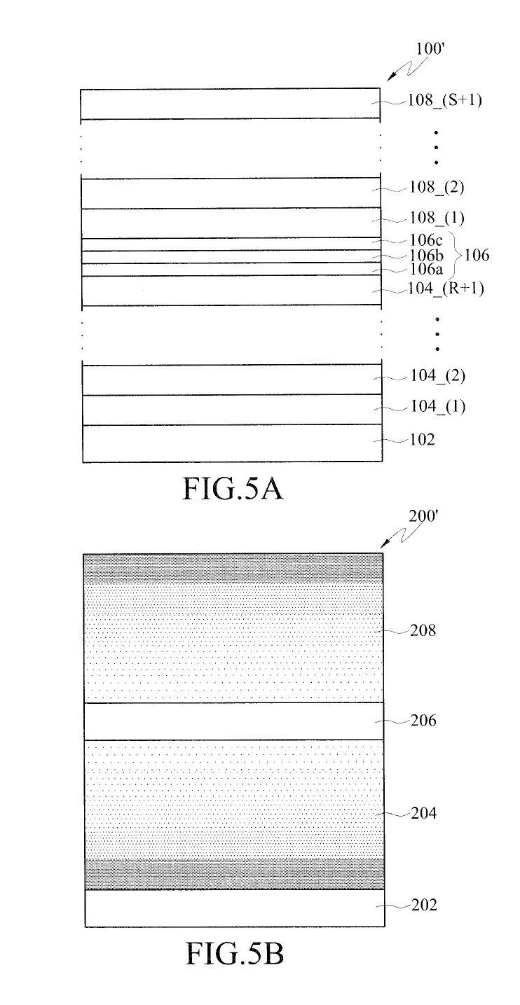

Similarly, in some embodiments, both the first contact region and the second contact region are made of single layer with decreasing dopant concentration gradient. FIG. 5A and FIG. 5B are cross-sectional structural views of a thin film solar cell of an embodiment. As shown in FIG. 5A, both the N-type dopant concentrations of the first contact region 104 and the second contact region 106 of the thin film solar cell 100′ decrease towards the photoelectric conversion layer 106. As shown in FIG. 5B, both the N-type dopant concentrations of the first contact region 204 and the second contact region 206 of the thin film solar cell 200′ decrease towards the photoelectric conversion layer 206. The type of the second contact region 108 is the same as that of the semiconductor layer of the photoelectric conversion layer 106 in contact with the second contact region 108, such as N-type; similarly, the type of the second contact region 208 is the same as that of the semiconductor layer of the photoelectric conversion layer 206 in contact with the second contact region 208, such as N-type. Furthermore, the valences of the dopants of the photoelectric conversion layers 106 and 206 are different from those of the second contact regions 108 and 208. Accordingly, comparing with the prior art, the solar cell 100′ and 200′ has better photoelectric conversion efficiency.

To sum up, in the thin-film solar cell and the method for manufacturing the same according to the present disclosure, at least one of the dopant concentrations of the first contact region and the second contact region decreases toward the photoelectric conversion layer, so that the dopant concentration on at least one of the contact interfaces between the first contact region as well as the second contact and the photoelectric conversion layer is decreased, thereby the photoelectric conversion efficiency of the solar cell is improved. The structure of the contact regions may be either the multi-layer structure shown in FIG. 3A, FIG. 3B, and FIG. 5A or the gradient structure shown in FIG. 4A, FIG. 4B, and FIG. 5B, which can achieve the inventive objectives of the present disclosure.

In addition, when the N-type dopant concentration of the surface of the contact region is low, and the P-type semiconductor is in contact with such surface, the contact barrier, i.e. the schottcky barrier is also low. When the N-type dopant concentration of the surface of the contact region is low, and the N-type semiconductor is in contact with such surface, the diffusion of the dopant is suppressed due to lower concentration gradient. In addition, when the N-type dopant concentration of the bottom of the contact region is high, the overall sheet resistance of the contact layer is reduced no matter they are joined with the P-type or the N-type semiconductor layer. That the dopant concentration of the contact region turns low on a sloping way towards the end of the contact region which is in contact with the P-type semiconductor layer of the photoelectric conversion layer has the advantage of low contact barrier and can make the contact region has low resistance, thereby improving the efficiency of the solar cell. On the other hand, that the dopant concentration of the contact region turns low on a sloping way towards the end of the contact region which is in contact with the N-type semiconductor layer of the photoelectric conversion layer has the advantage of reducing the diffusion of the N-type dopannts and can make the contact region has low resistance, thereby improving the efficiency of the solar cell.

What is claimed is:

1. A thin-film solar cell, comprising:
a substrate;
a first contact region, disposed on the substrate;
a photoelectric conversion layer, disposed on the first contact region; and
a second contact region, disposed on the photoelectric conversion layer,
wherein at least one of the first contact region and the second contact region contains N-type dopants, and the concentration of the N-type dopant turns low in a sloping way towards the photoelectric conversion layer.

2. The thin-film solar cell according to claim 1, wherein the first contact region contains the N-type dopants, and the first contact region comprises:
a first contact layer, disposed on the substrate; and
at least one buffer contact layer, disposed on the first contact layer, wherein the concentration of the N-type dopant contained in the first contact layer is higher than that of the N-type dopant contained in the at least one buffer contact layer.

3. The thin-film solar cell according to claim 1, wherein the second contact region contains the N-type dopants, and the second contact region comprises:
at least one buffer contact layer, disposed on the photoelectric conversion layer; and
a second contact layer, disposed on the at least one buffer contact layer, wherein the concentration of the N-type dopant contained in the second contact layer is higher than that of the N-type dopant contained in the at least one buffer contact layer.

4. The thin-film solar cell according to claim 1, wherein the first contact region and the second contact region both contain the N-type dopant, the first contact region comprises a first contact layer and at least one first buffer contact layer, the second contact region comprises a second contact layer and at least one second buffer contact layer, the first contact layer is disposed on the substrate, the first buffer contact layer is disposed on the first contact layer, the concentration of the N-type dopant contained in the first contact layer is higher than that of the N-type dopant contained in the first buffer contact layer, the second buffer contact layer is disposed on the photoelectric conversion layer, the second contact layer is disposed on the second buffer contact layer, and the concentration of the N-type dopant contained in the second contact layer is higher than that of the N-type dopant contained in the second buffer contact layer.

5. The thin-film solar cell according to claim 1, wherein the photoelectric conversion layer comprises:
a P-type semiconductor layer, adjacent to the first contact region; and
an N-type semiconductor layer, adjacent to the second contact region.

6. The thin-film solar cell according to claim 1, wherein the N-type dopant is selected from the group consisting of boron (B), aluminum (Al), gallium (Ga), and indium (In).

7. A method for manufacturing a thin-film solar cell, comprising:
forming a first contact region on a substrate;
forming a photoelectric conversion layer on the first contact region; and
forming a second contact region on the photoelectric conversion layer,
wherein at least one of the first contact region and the second contact region contains N-type dopants, and the concentration of the N-type dopant turns low in a sloping way towards the photoelectric conversion layer.

8. The method for manufacturing the thin-film solar cell according to claim 7, wherein the step of forming the first contact region comprises:
forming (R+1) contact material layers on the substrate sequentially, wherein the concentration of the N-type dopant of an R^{th} contact material layer is higher than that of an (R+1)^{th} contact material layer, and R is a positive integer.

9. The method for manufacturing the thin-film solar cell according to claim 7, wherein the step of forming the first contact region comprises:
forming a transparent conductive oxide (TCO) on the substrate; and
doping the TCO layer with the N-type dopant.

10. The method for manufacturing the thin-film solar cell according to claim 7, wherein the step of forming the second contact region comprises:
forming (S+1) contact material layers on the photoelectric conversion layer sequentially, wherein the concentration of the N-type dopant of an S^{th} contact material layer is lower than that of an (S+1)^{th} contact material layer, and S is a positive integer.

11. The method for manufacturing the thin-film solar cell according to claim 7, wherein the step of forming the second contact region comprises:
a transparent conductive oxide (TCO) layer is formed on the photoelectric conversion layer; and
doping the TCO layer with the N-type dopant.
